(19) United States
(12) Patent Application Publication
(10) Pub. No.: US 2023/0229207 A1
(43) Pub. Date: Jul. 20, 2023

(54) INTERNAL AIR CIRCULATION COMPONENT FOR A COMPUTING DEVICE

(71) Applicant: Dell Products L.P., Round Rock, TX (US)

(72) Inventors: Ayedin Nikazm, Austin, TX (US); Eric Michael Tunks, Austin, TX (US)

(21) Appl. No.: 17/576,736

(22) Filed: Jan. 14, 2022

(51) Int. Cl. G06F 1/20; H05K 7/20

(52) U.S. Cl. CPC G06F 1/20; H05K 7/20836; H05K 7/20736

(57) ABSTRACT

A computing device includes an air circulation component, a plurality of environmental control components, and a heating and cooling control component. The air circulation component, when powered, circulates air in an internal volume of the computing device. The plurality of environmental control components, when powered, draws air through the computing device. The heating and cooling control component manages the air circulation component and the plurality of environmental control components by powering the air circulation component and not powering the plurality of environmental control components when a temperature of the internal volume of the computing device is below a threshold temperature.

### BACKGROUND

Computing devices may perform services. In order to provide the services, the computing devices may include hardware components and software components. The software components may utilize the hardware components to provide the services.

### SUMMARY

In general, in one aspect, the invention relates to a computing device. The computing device includes an air circulation component, a plurality of environmental control components, and a heating and cooling control component. The air circulation component, when powered, circulates air in an internal volume of the computing device. The plurality of environmental control components, when powered, draws air through the computing device. The heating and cooling control component is configured to manage the air circulation component and the plurality of environmental control components by powering the air circulation component and not powering the plurality of environmental control components when a temperature of the internal volume of the computing device is below a threshold temperature.

In general, in one aspect, the invention relates to an information handling system including a cabinet housing a plurality of computing devices. Each computing device includes an air circulation component, a plurality of environmental control components, and a heating and cooling control component. The air circulation component, when powered, circulates air in an internal volume of the computing device. The plurality of environmental control components, when powered, draws air through the computing device. The heating and cooling control component is configured to manage the air circulation component and the plurality of environmental control components by powering the air circulation component and not powering the plurality of environmental control components when a temperature of the internal volume of the computing device is below a threshold temperature.

### BRIEF DESCRIPTION OF DRAWINGS

Certain embodiments of the invention will be described with reference to the accompanying drawings. However, the accompanying drawings illustrate only certain aspects or implementations of the invention by way of example, and are not meant to limit the scope of the claims.

FIG. 1 shows a diagram of an information handling system in accordance with one or more embodiments of the invention.

FIG. 2 shows a diagram of a computing device in accordance with one or more embodiments of the invention.

FIG. 3 shows a top-view of a portion of a computing device in accordance with one or more embodiments of the invention.

FIG. 4.1 shows a flowchart of a method for managing a temperature of an internal volume of a computing device in accordance with one or more embodiments of the invention.

FIG. 4.2 shows a flowchart of a method for managing a temperature of an internal volume of a computing device in accordance with one or more embodiments of the invention.

### DETAILED DESCRIPTION

Specific embodiments will now be described with reference to the accompanying figures. In the following description, numerous details are set forth as examples of the invention. It will be understood by those skilled in the art that one or more embodiments of the present invention may be practiced without these specific details, and that numerous variations or modifications may be possible without departing from the scope of the invention. Certain details known to those of ordinary skill in the art are omitted to avoid obscuring the description.

In the following description of the figures, any component described with regard to a figure, in various embodiments of the invention, may be equivalent to one or more like-named components described with regard to any other figure. For brevity, descriptions of these components will not be repeated with regard to each figure. Thus, each and every embodiment of the components of each figure is incorporated by reference and assumed to be optionally present within every other figure having one or more like-named components. Additionally, in accordance with various embodiments of the invention, any description of the components of a figure is to be interpreted as an optional embodiment, which may be implemented in addition to, in conjunction with, or in place of the embodiments described with regard to a corresponding like-named component in any other figure.

Throughout the application, ordinal numbers (e.g., first, second, third, etc.) may be used as an adjective for an element (i.e., any noun in the application). The use of ordinal numbers is not to imply or create any particular ordering of the elements nor to limit any element to being only a single element unless expressly disclosed, such as by the use of the terms “before”, “after”, “single”, and other such terminology. Rather, the use of ordinal numbers is to distinguish between the elements. By way of an example, a first element is distinct from a second element, and the first element may encompass more than one element and succeed (or precede) the second element in an ordering of elements.

As used herein, the phrase operatively connected, or operative connection, means that there exists between elements/components/devices a direct or indirect connection that allows the elements to interact with one another in some way. For example, the phrase ‘operatively connected’ may refer to any direct (e.g., wired directly between two devices or components) or indirect (e.g., wired and/or wireless connections between any number of devices or components connecting the operatively connected devices) connection. Thus, any path through which information and/or power may travel may be considered an operative connection.

Computing devices may include any number of hardware components that facilitate providing the services of the computing devices. The hardware components may include, for example, processors, non-persistent storage drives, persistent storage drives, circuit cards that interconnect these components, etc. In some cases, computing devices might be deployed in environments that result in the temperature of the computing devices being outside of their designed operating range. For example, the computing devices may be designed to operate at temperatures above 0° C. When the computing devices are deployed to harsh environmental conditions (e.g., −40° C.-60° C.), the computing devices may not operate properly and, in certain scenarios, may be damaged.

To address one or more of the aforementioned issues, embodiments of the invention provide a mechanism to manage a temperature of an internal volume of a computing device. More specifically, embodiments of the invention include an air circulation component, when powered, circulates air within the internal volume of the computing device. In one or more embodiments of the invention, the positioning of the air circulation component enables an airflow direction orthogonal to the airflow direction of at least one of a plurality of environmental control components.

Various embodiments of the computing device are described below.

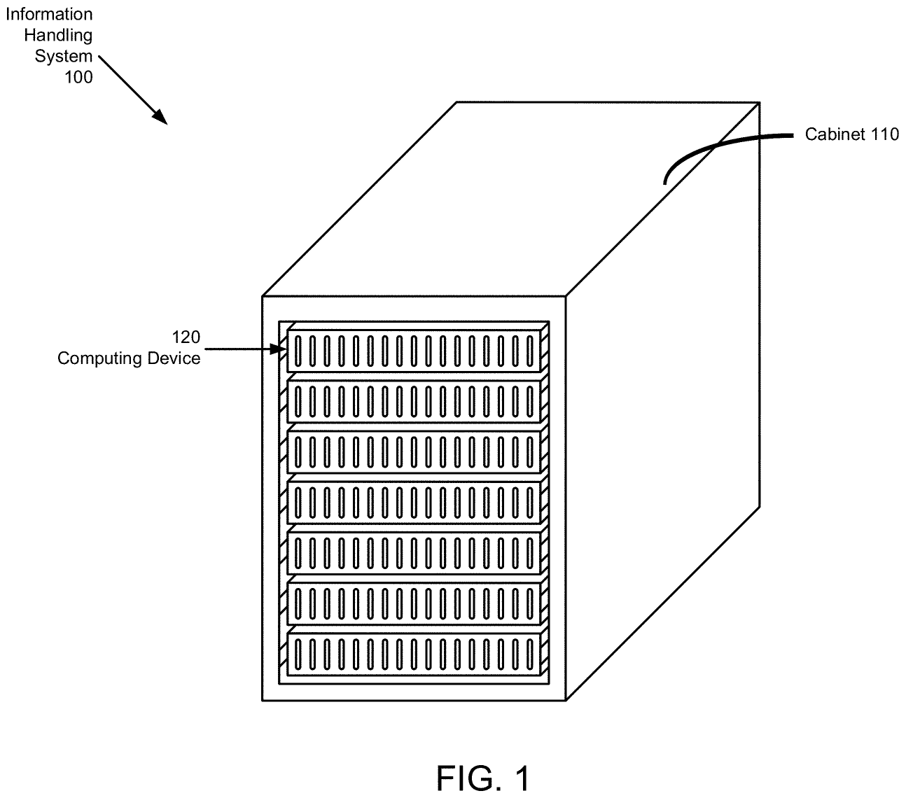

FIG. 1 shows a diagram of an information handling system (100) in accordance with one or more embodiments of the invention. The system may include a cabinet (110) and any number of computing devices (e.g., 120).

The cabinet (110) may be a mechanical structure that enables computing devices (e.g., 120) to be positioned with respect to one another. For example, the cabinet (110) may be a rack mountable enclosure that enables the computing devices (e.g., 120) to be disposed within it. The cabinet (110) may be implemented as other types of structures adapted to house, position, orient, and/or otherwise physically, mechanically, electrically, and/or thermally manage the computing devices (e.g., 120). By managing the computing devices (e.g., 120), the cabinet (110) may enable multiple computing devices to be densely packed in a space without negatively impacting the operation of the information handling system (100).

A computing device (e.g., 120) may be a mechanical structure for housing components of the information handling system (100). For example, the computing device (e.g., 120) may be implemented as a rack mountable enclosure for housing components of the information handling system. The computing device (e.g., 120) may be adapted to be disposed within the cabinet (110) and/or utilize services provided by the cabinet (110) and/or other devices.

To provide services, the computing device (e.g., 120) may utilize computing device resources provided by hardware components. The hardware components may include, for example, processors, non-persistent storage drives, a printed circuited board(s), persistent storage drives, special purpose hardware, and/or other types of physical components that contribute to the operation of the computing device.

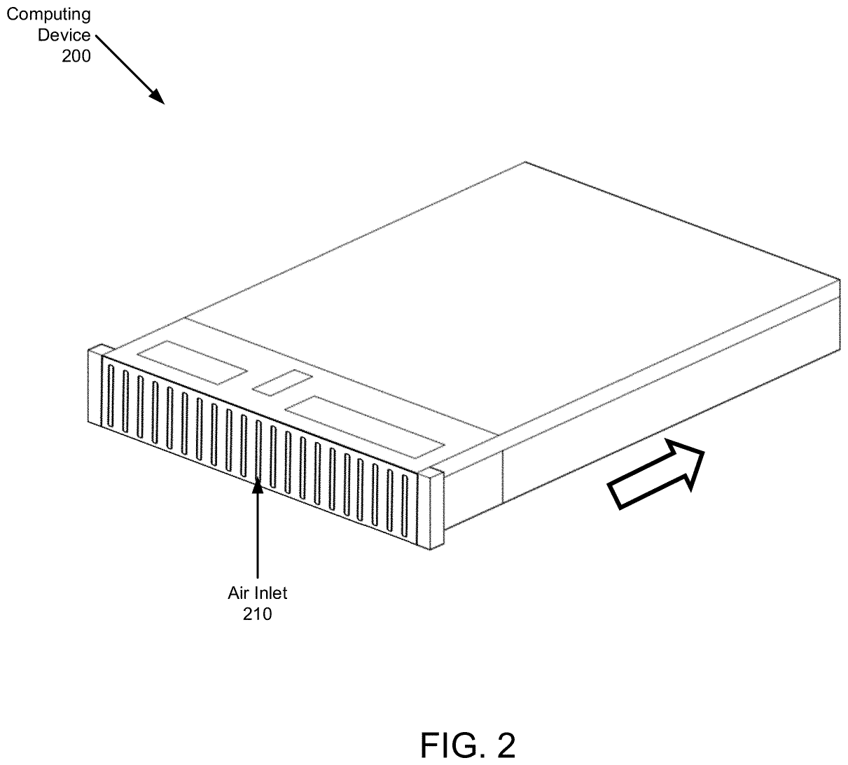

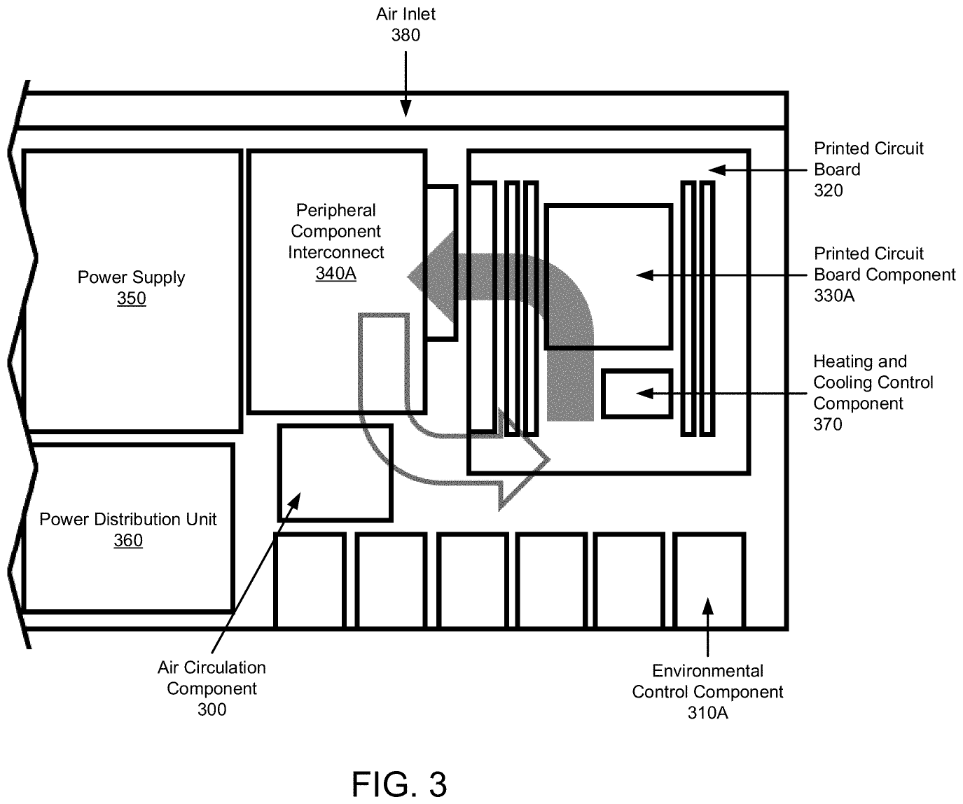

Turning now to FIG. 2, FIG. 2 shows a diagram of a computing device (200) in accordance with one or more embodiments of the invention. In one or more embodiments of the invention, the computing device includes six sides (i.e., top, bottom, right, left, front, and back), where air drawn into from the frontside of the computing device (i.e., via an air inlet (210)) and expelled from the backside of the computing device (i.e., via a number of environmental control components (e.g., 310A, FIG. 3)) (airflow direction is shown with an arrow). In general, air incoming from the frontside of the computing device is cooler than air outgoing from the backside of the computing device.

An air circulation component located in the internal volume of the computing device may improve stability and functionality of the computing device as it provides computer-implemented services in harsh environmental conditions. To provide services, the computing device (200) may utilize computing device resources provided by a number of hardware components housed within the computing device. The number of hardware components may include, for example, persistent storage drives (not shown), non-persistent storage drives (not shown), processors (not shown), peripheral component interconnects (not shown), a printed circuit board (not shown), and/or other types of physical components that contribute to the operation of the computing device (200). Some examples of the hardware components are shown in FIG. 3, but the examples of the hardware components are not limited to those shown in FIG. 3. In other embodiments, one or more of the hardware components may be omitted or additional hardware components may be added based on the services provided by the computing device.

Turning now to FIG. 3, FIG. 3 shows a top-view of a portion of a computing device in accordance with one or more embodiments of the invention. In one or more embodiments of the invention, the top-view of the portion of the computing device includes an air circulation component (300), a number of environmental control components (e.g., 310A), a printed circuit board (320), a number of printed circuit board components (e.g., 330A), a number of peripheral component interconnects (e.g., 340A), a power supply (350), a power distribution unit (360), a heating and cooling control component (370), an air inlet (380), and a number of temperature sensors (not shown). In an embodiment of the invention shown in FIG. 3, the airflow direction is shown with an arrow.

In one embodiment of the invention, the air circulation component (300) may include physical devices that provide functionality to change a temperature of the internal environment of the computing device (e.g., 200, FIG. 2). In one embodiment of the invention, the air circulation component (300) may include gas movers such as fans. These fans may distribute cold air taken from an air inlet of the air circulation component to a hotter region(s) in the computing device via an air outlet of the air circulation component to reduce a temperature of the hardware components located in the hotter region(s) of the computing device. Further, these fans may distribute hot air taken from the air inlet of the air circulation component to a colder region(s) in the computing device via the air outlet of the air circulation component to increase the temperature of the hardware components located in the colder region(s) of the computing device.

In one embodiment of the invention, the power supply (350) provides DC power to one or more other components in the computing device. Further, the power supply may include functionality to convert AC power (obtained from an external source) to DC power. In one embodiment of the invention, the power distribution unit (360) includes functionality to determine which hardware components receive power (i.e., power supplied by the power supply). For example, when the air circulation component (300) is to be activated, the power distribution unit may be instructed (e.g., by the heating and cooling control component) to distribute power (i.e., provide power) to the air circulation component.

In one or more embodiments of the invention, the number of environmental control components (e.g., 310A) may include physical devices that provide functionality to alter characteristics (e.g., airflow directions, humidity and temperature levels, etc.) of the internal environment of the computing device (e.g., 200, FIG. 2) at a macroscopic level. For example, the number of environmental control components (e.g., 310A) may include gas movers such as fans. The fans may be able to change a rate of gases drawn into and expelled from the computing device.

In one or more embodiments of the invention, the heating and cooling control component (370) may provide heating or cooling control services. The heating or cooling control services may include (i) obtaining information regarding the temperature of one or more hardware components within the computing device (e.g., 200, FIG. 2), where the information may be obtained wirelessly or via the number of temperature sensors in the computing device, (ii) determining whether the temperature within the computing device is below or above the appropriate operating temperature range, (iii) initiating a heating process or a cooling process to bring the hardware components of the computing device into their designed operating temperature, and (iv) preventing damage to the hardware components in the computing device in the event of overheating or freezing.

While described as a physical structure, the heating and cooling control component (370) may be implemented as a logical entity (e.g., a program executing using the number of printed circuit board components (e.g., 330A)). For example, the computing device (e.g., 200, FIG. 2) may host a program that provides the functionality of the heating and cooling control component (not shown). Those skilled in the art will appreciate that while the heating and cooling control component (370) is shown that it is located on top of the printed circuit board (320), it may be placed at any location within the computing device without departing from the invention.

With respect to the temperature sensors, the temperature sensors may be operatively connected to the heating and cooling control component (370) and to at least one of the hardware components (e.g., printed circuit board (320), air inlet (380), etc.) within the computing device (e.g., 200, FIG. 2).

Those skilled in the art will appreciate that while the printed circuit board (320), the number of printed circuit board components (e.g., 330A), the number of peripheral component interconnects (e.g., 340A), and the power supply (350) are shown that they are located at the frontside of the computing device, those components may be placed at any location within the computing device without departing from the invention. Similarly, while the number of environmental control components (e.g., 310A) is shown that they are located at the backside of the computing device, those components may be placed at any location within the computing device without departing from the invention.

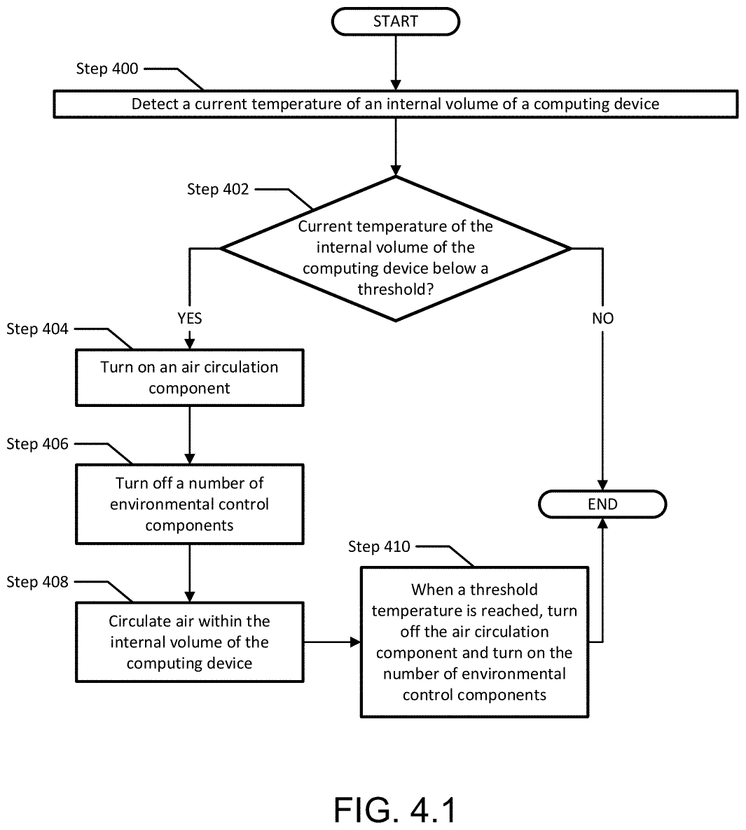

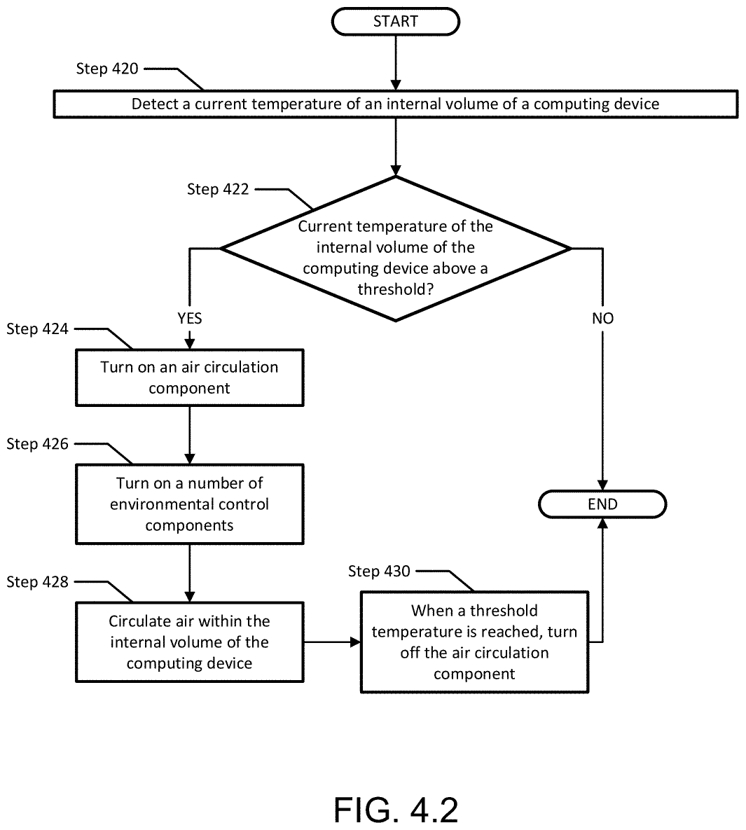

Turning now to FIG. 4.1, FIG. 4.1 shows a flowchart of a method for managing a temperature of an internal volume of a computing device in accordance with one or more embodiments of the invention. The method shown in FIG. 4.1 may be performed by, for example, a heating and cooling control component (e.g., 370, FIG. 3). Other hardware components of the computing device illustrated in FIG. 3 may perform all, or a portion, of the method shown in FIG. 4.1 without departing from the invention.

While FIG. 4.1 is illustrated as a series of steps, any of the steps may be omitted, performed in a different order, additional steps may be included, and/or any or all of the steps may be performed in a parallel and/or partially overlapping manner without departing from the invention.

In Step 400, a current temperature of an internal volume of a computing device is detected. In one or more embodiments of the invention, the current temperature of the internal volume of the computing device may be detected through a number of temperature sensors, which are operatively connected to at least one of the hardware components within the computing device.

In Step 402, a determination is made about whether the current temperature of the internal volume of the computing device is below a threshold (which may be a manufacture specified default value, a user defined value, etc.). The threshold may correspond to a temperature that is outside the operating temperature range of one or more components of the computing device. Further, with respect to FIG. 4.1, the threshold may be lower than the lower end of the operating temperature range. For example, if the operating temperature range is 0° C.-40° C., then the threshold may be −1° C. If the result of the determination is YES, which indicates the current temperature of the internal volume of the computing device is below the threshold, the method proceeds to Step 404. If the result of the determination is NO, which indicates the current temperature of the internal volume of the computing device is not below the threshold, the method ends.

In Step 404, an air circulation component is turned on. In one or more embodiments of the invention, the air circulation component is turned on by the heating and cooling control component. Turning on the air circulation component may result in the distribution of thermal energy (i.e., hot air in the internal volume of the computing device) to a colder region(s) in the computing device (shown with a black arrow in FIG. 3). This may result in an increase in a temperature of the hardware components that are located in the colder region(s) of the computing device. Specifically, the air circulation component facilitates the internal movement of air within the computing device and, as such, colder and warmer air (which is warmed via interaction with the other hardware components within the computing device) mixes resulting in an overall increase in air temperature within the computing device.

In Step 406, a number of environmental control components is turned off. In one or more embodiments of the invention, the number of environmental control components is turned off by the heating and cooling control component. Turning off the number of environmental control components may result in blocking, or at least significantly reducing, the expulsion of air in the internal volume of the computing device via the number of environmental control components. By this way, hot air kept in the internal volume of the computing device for heating the colder regions of the computing device more efficiently.

Continuing with the discussion of FIG. 4.1, in Step 408, air within the internal volume of the computing device is circulated by the air circulation component. In one or more embodiments of the invention, an airflow direction of the air circulation component is orthogonal to an airflow direction of at least one of the number of environmental control components. More specifically, air inlet and air outlet directions of the air circulation component are orthogonal to air inlet and air outlet directions of the at least one of the number of environmental control components. For example, based on the top-view of the portion of the computing device shown in FIG. 3, the airflow direction of the air circulation component is from rightside to leftside (e.g., towards from the heating and cooling control component to a power distribution unit), while the airflow direction of the at least one of the number of environmental control components is from topside to bottomside (e.g., towards from air inlet to the heating and cooling control component). By this way, a uniform air circulation in the internal volume of the computing device may be formed.

In Step 410, when a threshold temperature is reached, the heating and cooling control component turns off the air circulation component and turns on the number of environmental control components. In one or more embodiments of the invention, by turning off the air circulation component and turning on the at least one of the number of environmental control components, the air in the internal volume of the computing device may be expelled from the computing device. By this way, the computing device will be back to operate in its equilibrium condition.

The method ends following Step 410.

In one or more embodiments of the invention, with the help of Steps 404-410, circulation of air in the internal volume of the computing device is performed. The temperature of the internal volume of the computing device is averaged to prevent freezing of certain regions in the internal volume of the computing device. Further, the stability and functionality of the computing device may be improved.

Turning now to FIG. 4.2, FIG. 4.2 shows a flowchart of a method for managing a temperature of an internal volume of a computing device in accordance with one or more embodiments of the invention. The method shown in FIG. 4.2 may be performed by, for example, a heating and cooling control component (e.g., 370, FIG. 3). Other hardware components of the computing device illustrated in FIG. 3 may perform all, or a portion, of the method shown in FIG. 4.2 without departing from the invention.

While FIG. 4.2 is illustrated as a series of steps, any of the steps may be omitted, performed in a different order, additional steps may be included, and/or any or all of the steps may be performed in a parallel and/or partially overlapping manner without departing from the invention.

In Step 420, a current temperature of an internal volume of a computing device is detected. In one or more embodiments of the invention, the current temperature of the internal volume of the computing device may be detected through a number of temperature sensors, which are operatively connected to at least one of the hardware components within the computing device.

In Step 422, a determination is made about whether the current temperature of the internal volume of the computing device is above a threshold (which may be a manufacture specified default value, a user defined value, etc.). The threshold may correspond to a temperature that is outside the operating temperature range of one or more components of the computing device. Further, with respect to FIG. 4.2, the threshold may be higher than the upper end of the operating temperature range. For example, if the operating temperature range is 0° C.-40° C., then the threshold may be 41° C. If the result of the determination is YES, which indicates the current temperature of the internal volume of the computing device is above the threshold, the method proceeds to Step 424. If the result of the determination is NO, which indicates the current temperature of the internal volume of the computing device is not above the threshold, the method ends.

In Step 424, an air circulation component is turned on. In one or more embodiments of the invention, the air circulation component is turned on by the heating and cooling control component. Turning on the air circulation component may result in distributing thermal energy (i.e., cold air in the internal volume of the computing device) to a hotter region(s) in the computing device (shown with a white arrow in FIG. 3). This may result in a decrease in a temperature of the hardware components that are located in the hotter region(s) of the computing device.

In Step 426, a number of environmental control components is turned on. In one or more embodiments of the invention, the number of environmental control components is turned on by the heating and cooling control component. Turning on the number of environmental control components may result in allowing the expulsion of air in the internal volume of the computing device via the number of environmental control components.

Continuing with the discussion of FIG. 4.2, in Step 428, air within the internal volume of the computing device is circulated by the air circulation component. In one or more embodiments of the invention, an airflow direction of the air circulation component is orthogonal to an airflow direction of at least one of the number of environmental control components. More specifically, air inlet and air outlet directions of the air circulation component are orthogonal to air inlet and air outlet directions of the at least one of the number of environmental control components. For example, based on the top-view of the portion of the computing device shown in FIG. 3, the airflow direction of the air circulation component is from leftside to rightside (e.g., towards from a power distribution unit to the heating and cooling control component), while the airflow direction of the at least one of the number of environmental control components is from topside to bottomside (e.g., towards from air inlet to the heating and cooling control component). By this way, a uniform air circulation in the internal volume of the computing device may be formed.

In Step 430, when a threshold temperature is reached, the heating and cooling control component turns off the air circulation component. In one or more embodiments of the invention, by this way, the computing device will be back to operate in its equilibrium condition.

The method ends following Step 430.

In one or more embodiments of the invention, with the help of Steps 424-430, circulation of air in the internal volume of the computing device is performed. The temperature of the internal volume of the computing device is averaged to prevent overheating of certain regions in the internal volume of the computing device. Further, the stability and functionality of the computing device are improved.

In one or more embodiments of the invention, the heating and cooling control component may maintain multiple thresholds in order to implement both FIGS. 4.1 and 4.2.

The problems discussed above should be understood as being examples of problems solved by embodiments of the invention disclosed herein and the invention should not be limited to solving the same/similar problems. The disclosed invention is broadly applicable to address a range of problems beyond those discussed herein.

While the invention has been described above with respect to a limited number of embodiments, those skilled in the art, having the benefit of this disclosure, will appreciate that other embodiments can be devised which do not depart from the scope of the invention as disclosed herein. Accordingly, the scope of the invention should be limited only by the attached claims.

What is claimed is:

1. A computing device, comprising:
an air circulation component, when powered, circulates air in an internal volume of the computing device;
a plurality of environmental control components, when powered, draws air through the computing device; and
a heating and cooling control component configured to manage the air circulation component and the plurality of environmental control components by powering the air circulation component and not powering the plurality of environmental control components when a temperature of the internal volume of the computing device is below a threshold temperature.

2. The computing device of claim 1, wherein the heating and cooling control component is further configured to manage the air circulation component and the plurality of environmental control components by not powering the air circulation component when the temperature of the internal volume of the computing device is reached the threshold temperature.

3. The computing device of claim 2, wherein the heating and cooling control component is further configured to manage the air circulation component and the plurality of environmental control components by powering the plurality of environmental control components when the temperature of the internal volume of the computing device is above a second threshold temperature.

4. The computing device of claim 1, wherein the plurality of environmental control components is affixed to at least one side of the computing device.

5. The computing device of claim 1, wherein an airflow direction of the air circulation component is different from a second airflow direction of at least one of the plurality of environmental control components.

6. The computing device of claim 1, wherein an airflow direction of the air circulation component is orthogonal to a second airflow direction of at least one of the plurality of environmental control components.

7. The computing device of claim 1,
wherein the plurality of environmental control components is located on backside of the computing device,
wherein an air inlet is located on the frontside of the computing device; and
wherein the air circulation component is located between the frontside and the backside of the computing device.

8. A computing device, comprising:
an air circulation component, when powered, circulates air in an internal volume of the computing device;
a plurality of environmental control components, when powered, draws air through the computing device; and
a heating and cooling control component configured to manage the air circulation component and the plurality of environmental control components by powering the air circulation component and powering the plurality of environmental control components when a temperature of the internal volume of the computing device is above a threshold temperature.

9. The computing device of claim 8, wherein the heating and cooling control component is further configured to manage the air circulation component and the plurality of environmental control components by not powering the air circulation component when the temperature of the internal volume of the computing device is reached the threshold temperature.

10. The computing device of claim 9, wherein the heating and cooling control component is further configured to manage the air circulation component and the plurality of environmental control components by powering the plurality of environmental control components when the temperature of the internal volume of the computing device is above a second threshold temperature.

11. The computing device of claim 8, wherein the plurality of environmental control components is affixed to at least one side of the computing device.

12. The computing device of claim 8, wherein an airflow direction of the air circulation component is different than a second airflow direction of at least one of the plurality of environmental control components.

13. The computing device of claim 8, wherein an airflow direction of the air circulation component is orthogonal to a second airflow direction of at least one of the plurality of environmental control components.

14. The computing device of claim 8,
wherein the plurality of environmental control components is located on backside of the computing device,
wherein an air inlet is located on the frontside of the computing device; and
wherein the air circulation component is located between the frontside and the backside of the computing device.

15. An information handling system, comprising:
a cabinet housing a plurality of computing devices;
the plurality of computing devices, wherein each of the computing devices comprises:
an air circulation component, when powered, circulates air in an internal volume of the computing device;
a plurality of environmental control components, when powered, draws air through the computing device; and
a heating and cooling control component configured to manage the air circulation component and the plurality of environmental control components by powering the air circulation component and not powering the plurality of environmental control components when a temperature of the internal volume of the computing device is below a threshold temperature.

16. The information handling system of claim 15, wherein the heating and cooling control component is further configured to manage the air circulation component and the plurality of environmental control components by not powering the air circulation component when the temperature of the internal volume of the computing device is reached the threshold temperature.

17. The information handling system of claim 16, wherein the heating and cooling control component is further configured to manage the air circulation component and the plurality of environmental control components by powering the plurality of environmental control components when the temperature of the internal volume of the computing device is above a second threshold temperature.

18. The information handling system of claim 15, wherein the plurality of environmental control components is affixed to at least one side of the computing device.

19. The information handling system of claim 15, wherein an airflow direction of the air circulation component is different from a second airflow direction of at least one of the plurality of environmental control components.

20. The information handling system of claim 15, wherein an airflow direction of the air circulation component is orthogonal to a second airflow direction of at least one of the plurality of environmental control components.
